(19) United States
(12) Patent Application Publication
(10) Pub. No.: US 2026/0107822 A1
(43) Pub. Date: Apr. 16, 2026

(54) PACKAGE STRUCTURE

(71) Applicant: Advanced Semiconductor Engineering, Inc., Kaohsiung (TW)

(72) Inventors: Ko-Chun CHEN, Kaohsiung (TW); Lu-Ming LAI, Kaohsiung (TW)

(73) Assignee: Advanced Semiconductor Engineering, Inc., Kaohsiung (TW)

(21) Appl. No.: 18/913,951

(22) Filed: Oct. 11, 2024

(51) Int. Cl. H01L 23/31; H01L 21/56; H01L 23/00; H01L 23/24; H01L 23/29; H01L 25/065

(52) U.S. Cl. CPC H10W 74/121; H10W 74/114; H10W 74/40; H10W 76/47; H10W 72/0198; H10W 72/536; H10W 72/865; H10W 72/884; H10W 74/016; H10W 74/10; H10W 90/00; H10W 90/732; H10W 90/734; H10W 90/752; H10W 90/754

(57) ABSTRACT

A package structure is provided. The package structure includes a substrate, a first electronic component, an encapsulant, and a protective element. The first electronic component is over the substrate. The encapsulant is over the substrate and defines a cavity that exposes the first electronic component. The protective element covers the first electronic component. A lateral surface of the protective element is substantially aligned with a lateral surface of the encapsulant.

### BACKGROUND

### 1. Technical Field

The present disclosure relates generally to a package structure.

### 2. Description of the Related Art

In certain semiconductor devices or packages, such as those including a pressure sensing die, it is known to apply a gel over the pressure sensing die to protect the die while still allowing the die to sense the pressure outside the package, and a lid is further disposed to cover the pressure sensing die. The lid is attached to the substrate with the use of lid paste. However, the gel and the lid may increase the size of the semiconductor device or package.

### SUMMARY

In one or more arrangements, a package structure includes a substrate, a first electronic component, an encapsulant, and a protective element. The first electronic component is over the substrate. The encapsulant is over the substrate and defines a cavity that exposes the first electronic component. The protective element covers the first electronic component. A lateral surface of the protective element is substantially aligned with a lateral surface of the encapsulant.

In one or more arrangements, a package structure includes a substrate, an encapsulant, an electronic component, and a protective element. The encapsulant is over the substrate and defines a cavity. The electronic component is disposed within the cavity. The protective element covers the electronic component and is at least partially positioned over an upper surface of the encapsulant.

In one or more arrangements, a package structure includes a substrate, an electronic component over the substrate, and a pressure-sensitive protective element covering the electronic component. A lateral surface of the pressure-sensitive protective element is substantially aligned with a lateral surface of the substrate.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 1A is a cross-section of a portion of a package structure in accordance with some arrangements of the present disclosure.

FIG. 2A is a top view of a package structure in accordance with some arrangements of the present disclosure.

FIG. 2B is a cross-section of a package structure in accordance with some arrangements of the present disclosure.

FIG. 2C is a cross-section of a package structure in accordance with some arrangements of the present disclosure.

FIG. 2D is a side view of a package structure in accordance with some arrangements of the present disclosure.

FIG. 3A is a top view of a package structure in accordance with some arrangements of the present disclosure.

FIG. 3B is a cross-section of a package structure in accordance with some arrangements of the present disclosure.

FIG. 3C is a cross-section of a package structure in accordance with some arrangements of the present disclosure.

FIG. 4A is a cross-section of a package structure in accordance with some arrangements of the present disclosure.

FIG. 4B is a cross-section of a package structure in accordance with some arrangements of the present disclosure.

FIG. 4C is a cross-section of a portion of a package structure in accordance with some arrangements of the present disclosure.

FIG. 5 to FIG. 8B illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

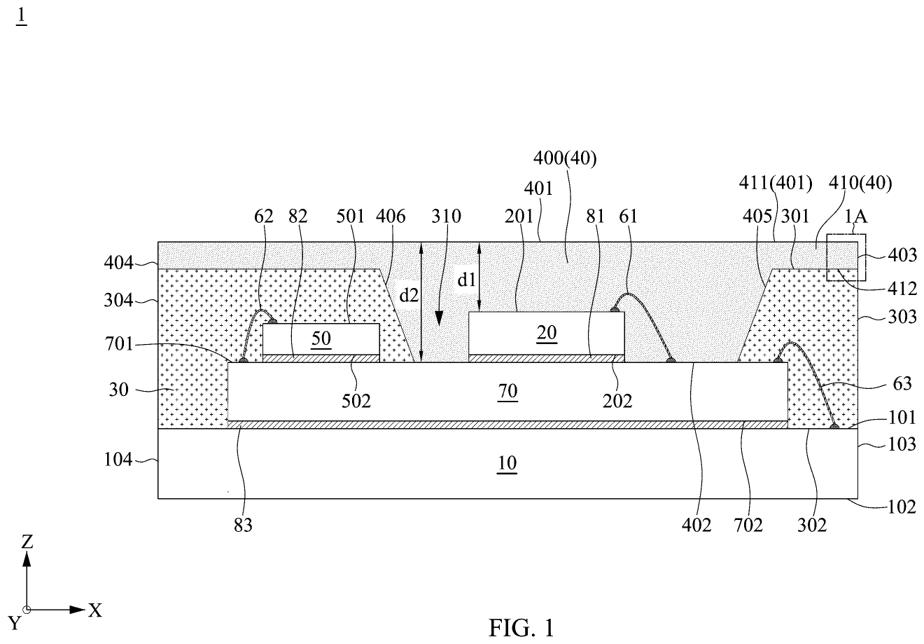

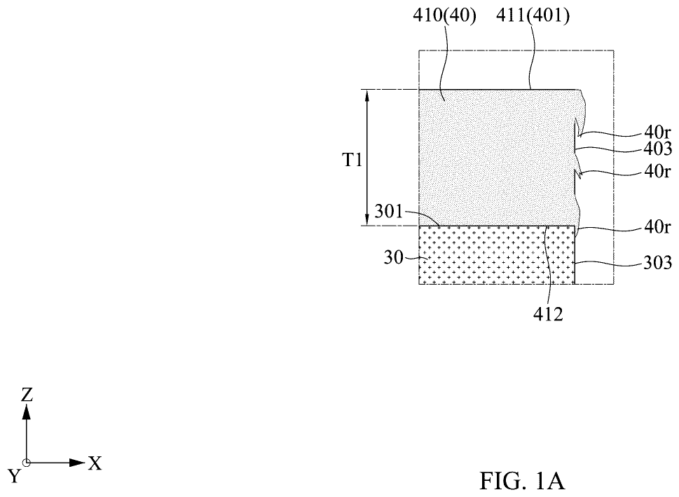

FIG. 1 is a cross-section of a package structure 1 in accordance with some arrangements of the present disclosure. FIG. 1A is a cross-section of a portion of a package structure 1 in accordance with some arrangements of the present disclosure. In some arrangements, FIG. 1A is a cross-section of a portion 1A of the package structure 1 illustrated in FIG. 1. The package structure 1 may include a substrate 10, electronic components 20, 50 and 70, an encapsulant 30, a protective element 40, conductive wires 61 and 62, and adhesive elements 81, 82, and 83.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may have a surface 101 (also referred to as “a top surface” or “an upper surface”), a surface 102 (also referred to as “a bottom surface” or “a lower surface”) opposite to the surface 101.

The electronic component 20 may be disposed over the substrate 10. The electronic component 20 may have a surface 201 (also referred to as “a top surface” or “an upper surface”) and a surface 202 (also referred to as “a bottom surface” or “a lower surface”) opposite to the surface 201. In some arrangements, the electronic component 20 includes a sensing component (e.g. a MEMS device, a pressure sensor, and an acceleration sensor), a processor (e.g., an ASIC, an FPGA, and a GPU), a controller (e.g. a memory controller), a microcontroller (MCU), a memory die, a power device, a high speed input/output (I/O) device, or other electronic component(s). In some arrangements, the electronic component 20 is configured to detect a pressure outside of the package structure 1. In some arrangements, the electronic component 20 is or includes a pressure sensor (also referred to as “a P-Cell”) or an inertial measurement unit (IMU) sensor.

The encapsulant 30 may be disposed over the substrate 10. In some arrangements, the encapsulant 30 defines a cavity 310. In some arrangements, the cavity 310 exposes the electronic component 20. In some arrangements, the electronic component 20 is disposed in the cavity 310. In some arrangements, a bottom surface 302 of the encapsulant 30 contacts or connects to the surface 101 of the substrate 10. In some arrangements, the upper surface 301 of the encapsulant 30 is free from being covered by a lid. In some arrangements, the upper surface 301 of the encapsulant 30 is free from contacting a lid. In some arrangements, the encapsulant 30 has a hardness or a surface hardness on a Shore D scale. In some arrangements, the encapsulant 30 has a hardness or a surface hardness from about 70 Shore D to 90 Shore D. The encapsulant 30 may include an epoxy resin having fillers dispersed therein, a molding compound (e.g., an epoxy molding compound or other molding compound), polyimide (PI), a phenolic compound or material, or a combination thereof.

The protective element 40 may be disposed over the electronic component 20. In some arrangements, the protective element 40 covers the electronic component 20. In some arrangements, a lateral surface 403 of the protective element 40 is substantially aligned with a lateral surface 303 of the encapsulant 30. In some arrangements, a lateral surface 404 of the protective element 40 is substantially aligned with a lateral surface 304 of the encapsulant 30. In some arrangements, a lateral surface 403 of the protective element 40 is substantially aligned with a lateral surface 103 of the substrate 10. In some arrangements, a lateral surface 404 of the protective element 40 is substantially aligned with a lateral surface 104 of the substrate 10. In some arrangements, the protective element 40 covers the electronic component 20 and is at least partially over the upper surface 301 of the encapsulant 30. In some arrangements, the protective element 40 is filled in the cavity 310 and has a substantially planar top surface 401 of the protective element 40. In some arrangements, the protective element 40 has surfaces 405 and 406 contacting the encapsulant 30 and inclined with respect to the surface 101 of the substrate 10. In some arrangements, the top surface (e.g., the surface 201) of the electronic component 20 is separated from the top surface 401 of the protective element 40 by a constant distance d1, and the distance d1 extends in a direction (e.g., z-axis) substantially perpendicular to the surface 101 of the substrate 10.

In some arrangements, the protective element 40 has a hardness or a surface hardness on a Shore OO scale. In some arrangements, the protective element 40 has a hardness or a surface hardness from about 10 Shore OO to 30 Shore OO. In some arrangements, a hardness of the encapsulant 30 is greater than a hardness of the protective element 40. In some arrangements, a Shore hardness of the encapsulant 30 is greater than a Shore hardness of the protective element 40. In some arrangements, the protective element 40 includes a pressure sensitive gel. In some arrangements, the protective element 40 includes a silicone gel and an adhesive composition different from the silicone gel. In some arrangements, the adhesive composition of the protective element 40 is free of an epoxy material. In some arrangements, the adhesive composition of the protective element 40 includes silane. In some arrangements, the protective element 40 includes fillers dispersed in the silicone gel.

In some arrangements, the protective element 40 includes a portion 410 over the upper surface 301 of the encapsulant 30. In some arrangements, the portion 410 has a top surface 411 (e.g., a portion of the top surface 401) and a lateral surface (e.g., the lateral surface 403 and/or 404) exposed by the encapsulant 30. In some arrangements, the portion 410 has a bottom surface 412 on and contacting the upper surface 301 of the encapsulant 30.

Referring to FIG. 1A, in some arrangements, a roughness of the lateral surface (e.g., the lateral surfaces 403 and/or 404) of the protective element 40 is greater than a roughness of the lateral surface (e.g., the lateral surfaces 303 and/or 304) of the encapsulant 30. In some arrangements, the protective element 40 includes one or more protrusions 40r protruding from one or more lateral surfaces (e.g., the lateral surfaces 403 and/or 404) of the protective element 40. In some arrangements, the protrusion 40r partially covers one or more lateral surfaces (e.g., the lateral surfaces 303 and/or 304) of the encapsulant 30. In some arrangements, the protrusions 40r may be or include burrs.

The electronic component 50 may be disposed over the substrate 10. The electronic component 50 may have a surface 501 (also referred to as “a top surface” or “an upper surface”) and a surface 502 (also referred to as “a bottom surface” or “a lower surface”) opposite to the surface 501. In some arrangements, the electronic component 50 is covered by the encapsulant 30. In some arrangements, the electronic component 50 includes a sensing component (e.g. a MEMS device, a pressure sensor, and an acceleration sensor), a processor (e.g., an ASIC, an FPGA, and a GPU), a controller (e.g. a memory controller), a microcontroller (MCU), a memory die, a power device, a high speed input/output (I/O) device, or other electronic component(s). In some arrangements, the electronic component 50 is configured to detect an acceleration of the package structure 1. In some arrangements, the electronic component 50 is or includes an acceleration sensor (also referred to as “a G-Cell”).

The electronic component 70 may be disposed over the substrate 10. The electronic component 70 may have a surface 701 (also referred to as “a top surface” or “an upper surface”) and a surface 702 (also referred to as “a bottom surface” or “a lower surface”) opposite to the surface 701. In some arrangements, the electronic component 70 is partially covered by the encapsulant 30 and partially exposed by the encapsulant 30. In some arrangements, a portion of the surface 701 is exposed to the cavity 310. In some arrangements, the electronic component 20 is disposed on and adhered to the electronic component 70 through the adhesive element 81. In some arrangements, the electronic component 50 is disposed on and adhered to the electronic component 70 through the adhesive element 82. In some arrangements, the electronic component 70 is disposed on and adhered to the substrate 10 through the adhesive element 83. The adhesive elements 81, 82, and 83 may independently be or include die attach films (DAFs). In some arrangements, the top surface (e.g., the surface 701) of the electronic component 70 is separated from the top surface 401 of the protective element 40 by a constant distance d2, and the distance d2 extends in a direction (e.g., z-axis) substantially perpendicular to the surface 101 of the substrate 10.

In some arrangements, the electronic component 70 includes a sensing component (e.g. a MEMS device, a pressure sensor, and an acceleration sensor), a processor (e.g., an ASIC, an FPGA, and a GPU), a controller (e.g. a memory controller), a microcontroller (MCU), a memory die, a power device, a high speed input/output (I/O) device, or other electronic component(s). In some arrangements, the electronic component 70 is or includes a microcontroller (MCU).

In some arrangements, the conductive wire 61 is electrically connected to the electronic component 20 and covered by the protective element 40. In some arrangements, the conductive wire 61 electrically connects the surface 201 (or an active surface) of the electronic component 20 to the surface 701 (or an active surface) of the electronic component 70. In some arrangements, the conductive wire 62 is electrically connected to the electronic component 50 and covered by the encapsulant 30. In some arrangements, the conductive wire 62 electrically connects the surface 501 (or an active surface) of the electronic component 50 to the surface 701 (or the active surface) of the electronic component 70. In some arrangements, the conductive wire 63 is electrically connected to the electronic component 70 and covered by the encapsulant 30. In some arrangements, the conductive wire 63 electrically connects the surface 701 (or the active surface) of the electronic component 70 to the surface 101 (or the active surface) of the substrate 10.

In some cases a gel may be dispensed over a pressure sensing die in a cavity of a mold, and a lid is further disposed on the mold to cover the pressure sensing die and the gel. However, the dispensed gel may climb up toward the top surface of the mold due to capillary action, preventing the lid from adhering to the top surface of the mold. Additionally, after the gel is cured, the gel may form a concave curved top surface due to gravity. Because of the above, it is necessary to control the amount of the gel so as to avoid dispensing too much gel, which could climb up towards the top surface of the mold and prevent the lid from adhering to the mold, or dispensing too little gel, which could result in the upper surface of the pressure sensing die being exposed from the concave curved upper surface of the gel. In addition, due to the concave curved upper surface of the gel, particles may be accumulated at the bottom of the concave portion and covered by the gel, and the lid for blocking the particles from accumulation may undesirably increase the package size.

According to some arrangements of the present disclosure, the protective element 40 covers the electronic component 20 and functions as a pressure-sensitive gel and a protective lid. As such, a metal lid that attaches to the encapsulant 30 is omitted, and the electronic component 20 can be protected by the protective element 40 and detect pressure through the pressure-sensitive gel of the protective element 40. Therefore, the package size (e.g., a height) of the package structure 1 can be reduced significantly without adversely affecting the performance of the electronic component 20, and the manufacturing cost can be reduced as well.

In addition, according to some arrangements of the present disclosure, the protective element 40 includes a pressure-sensitive gel and has a relatively planar top surface 401. Therefore, the stability and accuracy of the pressure sensing function can be increased. For example, the distance d1 between the sensing surface (e.g., the surface 201) of the electronic component 20 and the top surface 401 of the protective element 40 is relatively constant. Accordingly, the travelling distance of the sensed signal from outside of the package structure toward the sensing surface (or the surface 201) of the electronic component 20 is uniform over the sensing surface, such that the sensed signals (e.g., the detected pressure values) over the sensing surface are based on the substantially the same reference or standard (e.g., substantially the same travelling distance crossing the medium). Therefore, the stability and accuracy of the pressure sensing function can be increased.

Moreover, according to some arrangements of the present disclosure, the protective element 40 includes a pressure sensitive gel including an adhesive composition that is configured to increase the bonding between the protective element 40 and the encapsulant 30. For example, the protective element 40 may include a hydrophilic material, the encapsulant 30 may include a hydrophobic material, and the adhesive composition includes a material that can react with both materials of the protective element 40 and the encapsulant 30 and form a cross-linked structure or chemical bonding that connects the protective element 40 to the encapsulant 30. Therefore, the adhesion strength between the protective element 40 and the encapsulant 30 is relatively strong, and delamination between the protective element 40 and the encapsulant 30 can be prevented effectively.

Furthermore, according to some arrangements of the present disclosure, the hardness of the encapsulant 30 is greater than the hardness of the protective element 40. As such, the encapsulant 30 may serve to support the protective element 40 and protect the electronic components 20, 50, and 70, and the protective element 40 may serve to detect pressure outside of the package structure 1. Therefore, the pressure sensing ability and the protection function can be achieved by the arrangements of the protective element 40 and the encapsulant 30, and the relatively hard or rigid structure of the encapsulant 30 is advantageous to handling (e.g., pick-and-place) of the package structure 1 without damaging the package structure 1 or the components thereof.

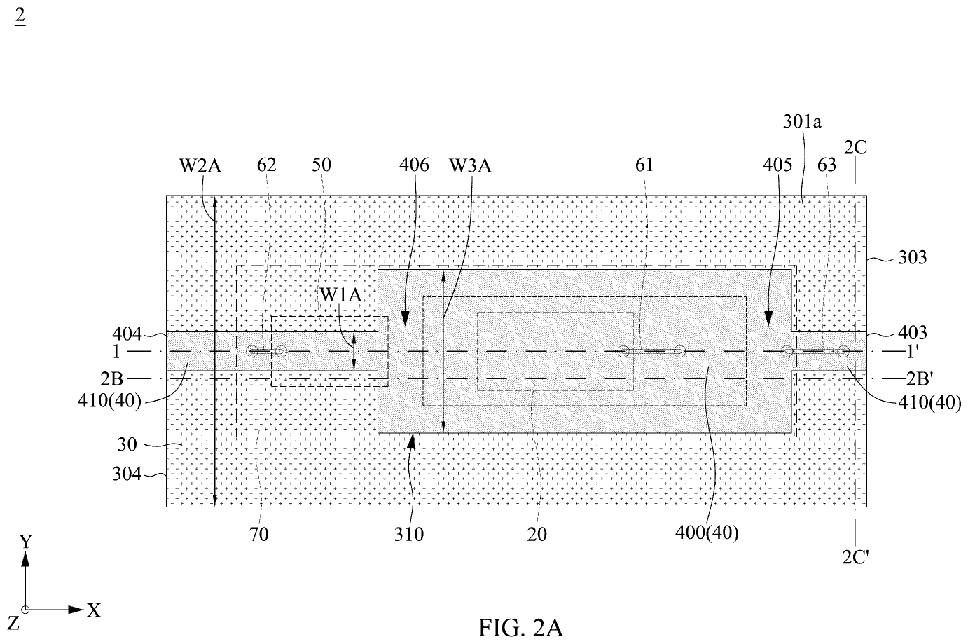

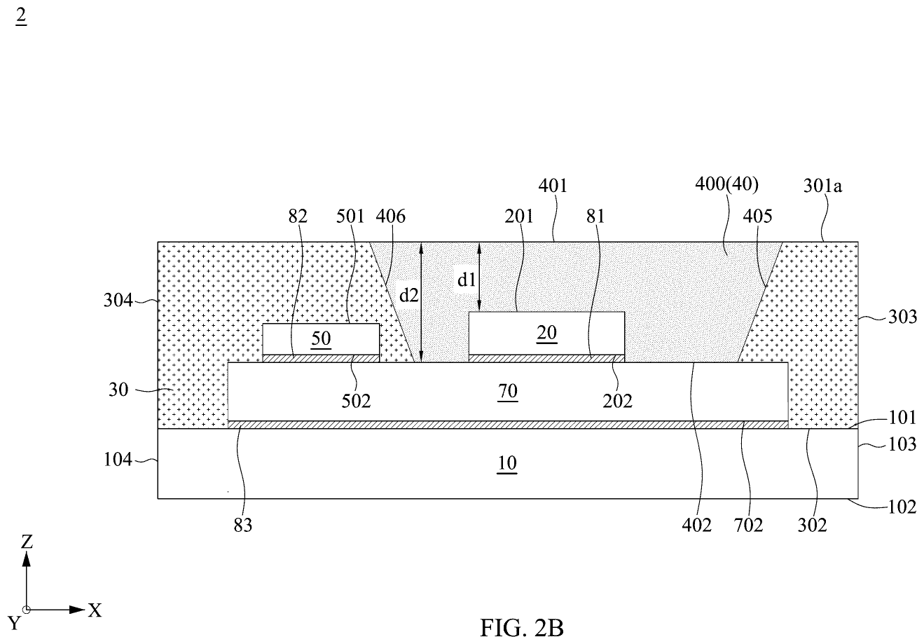

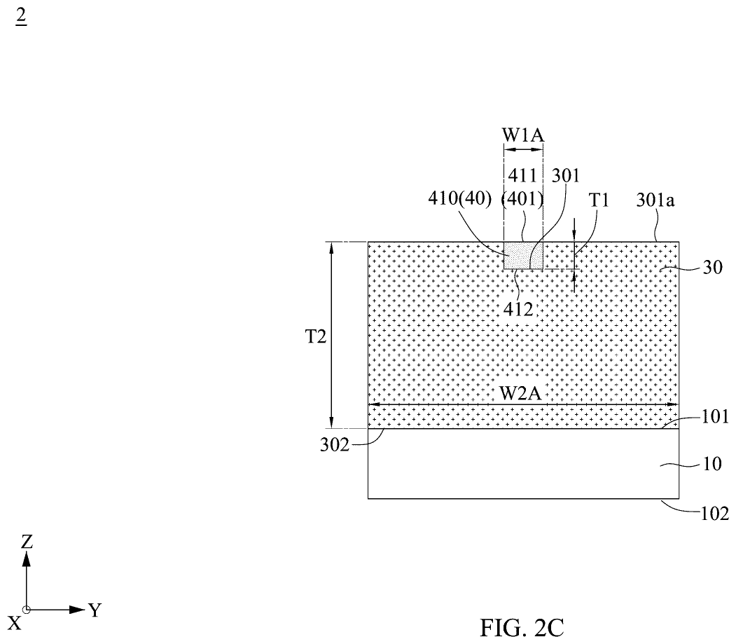

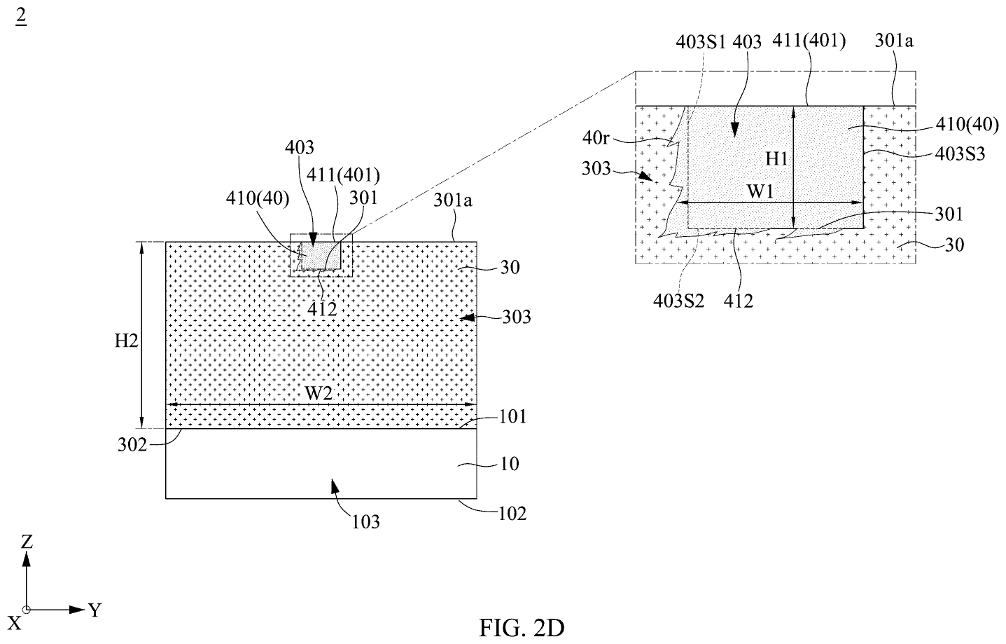

FIG. 2A is a top view of a package structure 2 in accordance with some arrangements of the present disclosure. FIG. 2B is a cross-section of a package structure 2 in accordance with some arrangements of the present disclosure. FIG. 2C is a cross-section of a package structure 2 in accordance with some arrangements of the present disclosure. In some arrangements, FIG. 1 is a cross-section along a line 1-1′ in FIG. 2A. In some arrangements, FIG. 2B is a cross-section along a line 2B-2B′ in FIG. 2A. In some arrangements, FIG. 2C is a cross-section along a line 2C-2C′ in FIG. 2A.

In some arrangements, the protective element 40 includes a portion 400 disposed in the cavity 310 and a portion 410 protruding beyond edges of the portion 400. In some arrangements, the portions 400 and 410 of the protective element 40 are embedded in the encapsulant 30 with top surfaces exposed by the encapsulant 30. In some arrangements, a width W1A of the portion 410 is less than a width W3A of the portion 400. In some arrangements, a width W1A of the portion 410 of the protective element 40 is less than a width W2A of the encapsulant 30.

Referring to FIG. 1, FIG. 2A, and FIG. 2B, in some arrangements, the portion 410 of the protective element 40 is over the upper surface 301 of the encapsulant 30 and embedded in the encapsulant 30. In some arrangements, the top surface 411 and the lateral surface 403 of the portion 410 of the protective element 40 are exposed by the encapsulant 30. In some arrangements, the encapsulant further has a top surface 301a at an elevation higher than that of the upper surface 301 with respect to the surface 101 of the substrate 10. In some arrangements, the top surface 411 of the portion 410 of the protective element 40 is exposed by and substantially coplanar with the top surface 301a of the encapsulant 30. In some arrangements, the top surface 401 of the portion 400 of the protective element 40 is exposed by and substantially coplanar with the top surface 301a of the encapsulant 30.

Referring to FIG. 2C, in some arrangements, a thickness T1 of the portion 410 of the protective element 40 is less than a thickness T2 of the encapsulant 30. In some arrangements, the bottom surface 412 of the portion 410 of the protective element 40 contacts the upper surface 301 of the encapsulant 30.

FIG. 2D is a side view of a package structure 2 in accordance with some arrangements of the present disclosure. In some arrangements, FIG. 2D is a side view of the structure illustrated in FIG. 1 and FIG. 2A as viewed in x-axis direction.

Referring to FIG. 2D, in some arrangements, an area of the lateral surface 403 of the protective element 40 (or the portion 410) is less than an area of the lateral surface 303 of the encapsulant 30. In some arrangements, a width W1 of the lateral surface 403 of the protective element 40 (or the portion 410) is less than a width W2 of the lateral surface 303 of the encapsulant 30. In some arrangements, a height H1 of the lateral surface 403 of the protective element 40 (or the portion 410) is less than a height H2 of the lateral surface 303 of the encapsulant 30.

In some arrangements, the protrusions 40r extend over a portion of the lateral surface 303 of the encapsulant 30. In some arrangements, the protrusions 40r may at least partially cover an interface 403S1 between the lateral surface 303 and the lateral surface 403. In some arrangements, the protrusions 40r may at least partially cover two or more interfaces (e.g., interfaces 403S1 and 403S2) between the lateral surface 303 and the lateral surface 403. In some arrangements, the protrusions 40r may be free from covering at least an interface 403S3 between the lateral surface 303 and the lateral surface 403. The protrusions 40r (or the burrs) may be formed by a mechanical cutting operation using a rotary saw blade during singulation. The relatively soft material of the protective element 40 may be pulled or dragged by the rotary saw blade and extending or stretched in the direction of the rotary saw blade's movement, such that the extended or stretched portions of the protective element 40 form the protrusions 40r (or the burrs) that partially cover the lateral surface 303 of the encapsulant 30.

According to some arrangements of the present disclosure, an area of the lateral surface 403 of the protective element 40 (or the portion 410) is less than an area of the lateral surface 303 of the encapsulant 30. The lateral surfaces 303 and 403 may be formed by mechanical cutting or mechanical dicing, and the relatively soft material of the protective element 40 may form burrs easily. With the design of the relatively small lateral surface 403 resulted from a relatively small cutting cross-section, the formation of burrs can be mitigated or even prevented.

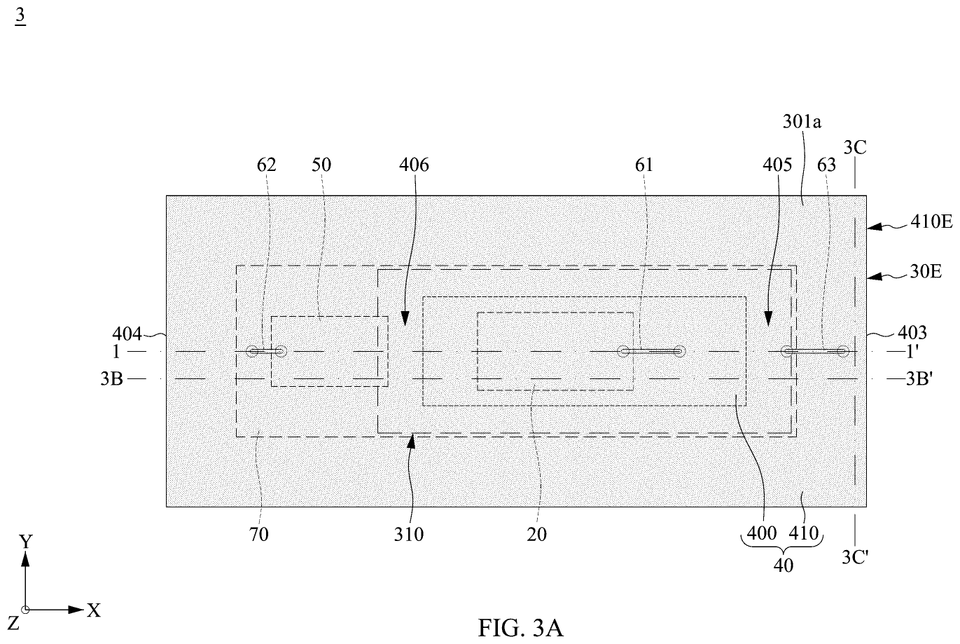

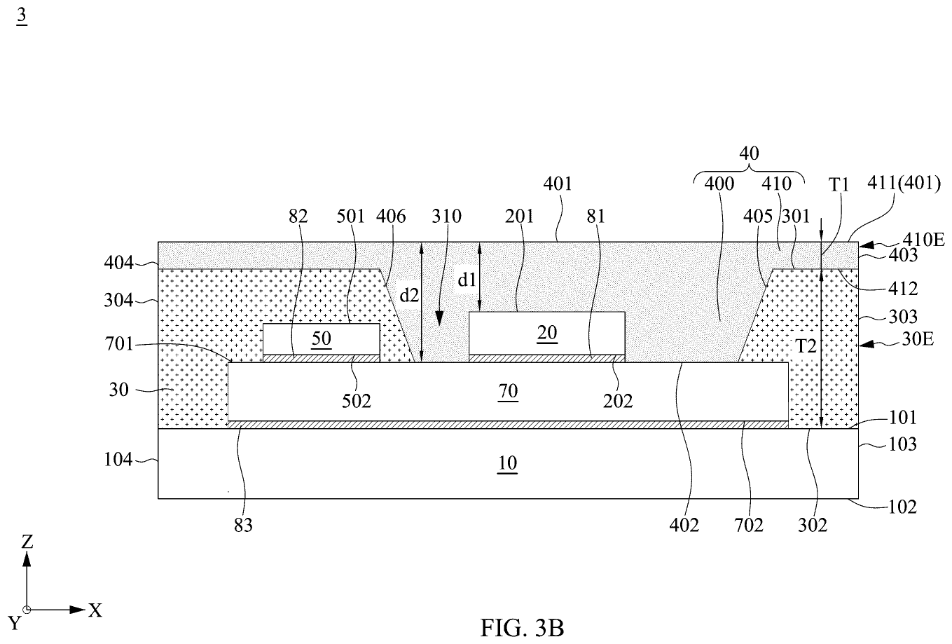

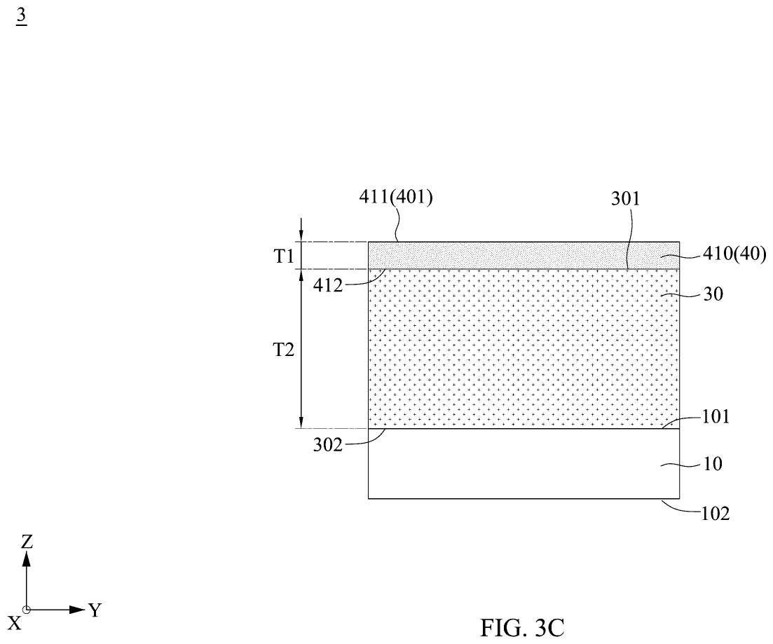

FIG. 3A is a top view of a package structure 3 in accordance with some arrangements of the present disclosure. FIG. 3B is a cross-section of a package structure 3 in accordance with some arrangements of the present disclosure. FIG. 3C is a cross-section of a package structure 3 in accordance with some arrangements of the present disclosure. In some arrangements, FIG. 1 is a cross-section along a line 1-1′ in FIG. 3A. In some arrangements, FIG. 3B is a cross-section along a line 3B-3B′ in FIG. 3A. In some arrangements, FIG. 3C is a cross-section along a line 3C-3C′ in FIG. 3A. The package structure 3 is similar to the package structure 1 in FIG. 1 and/or the package structure 2 in FIGS. 2A-2D, and the differences therebetween are described as follows.

In some arrangements, the protective element 40 is filled in the cavity 310 and covers the upper surface 301 of the encapsulant 30. In some arrangements, the protective element 40 covers the entire upper surface 301 of the encapsulant 30.

In some arrangements, the protective element 40 includes a portion 400 filled in the cavity 310 and a portion 410 over the portion 400. In some arrangements, the portion 410 of the protective element 40 covers the entire upper surface 301 of the encapsulant 30. In some arrangements, the portion 410 of the protective element 40 has a peripheral edge 410E substantially aligned with a peripheral edge 30E of the encapsulant 30. In some arrangements, the portion 410 of the protective element 40 is or includes a protective layer that has a consistent thickness (e.g., the thickness T1) and over the encapsulant 30 and the portion 400 of the protective element 40. In some arrangements, a projection of the portion 410 of the protective element 40 substantially overlaps the surface 101 of the substrate 10 from a top view perspective.

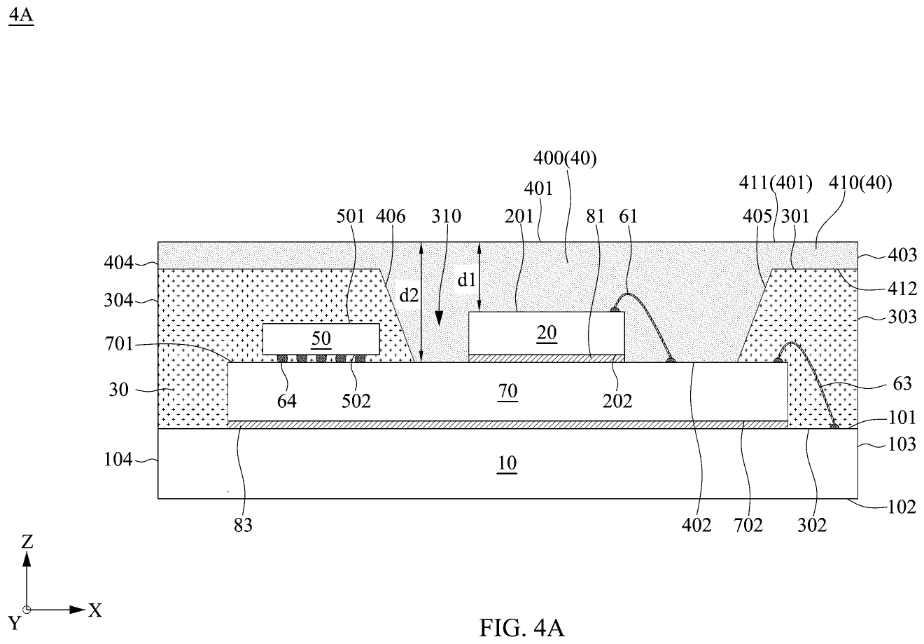

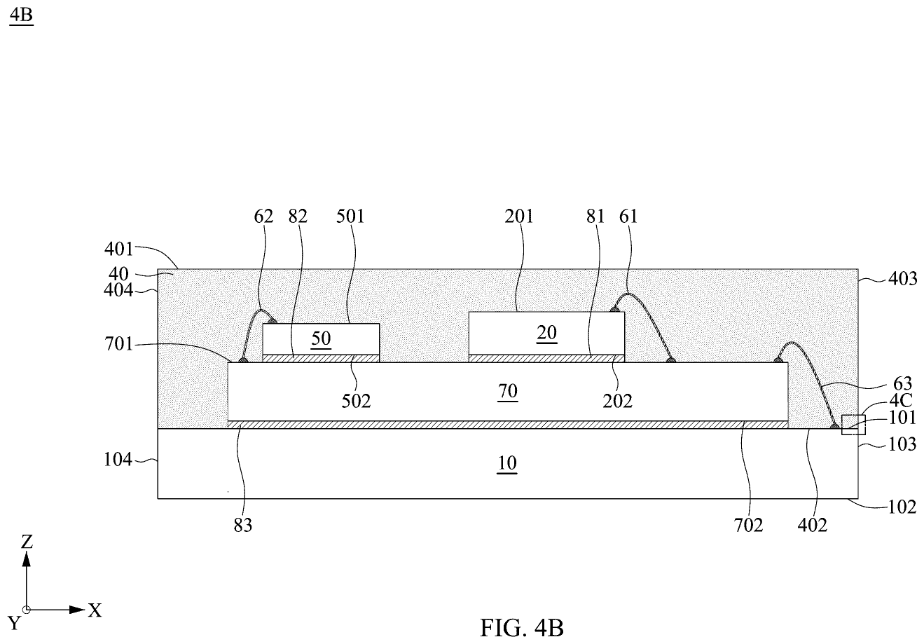

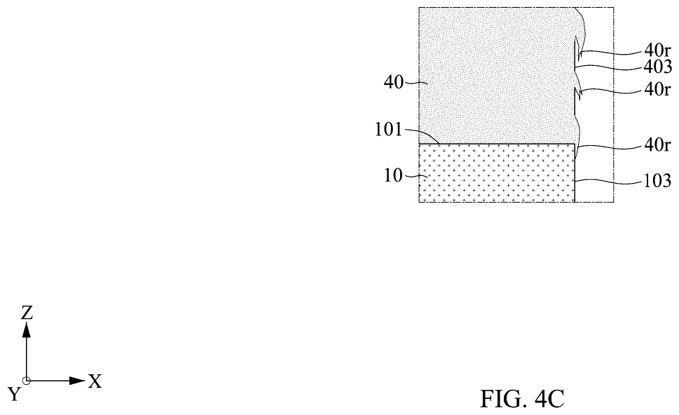

FIG. 4A is a cross-section of a package structure 4A in accordance with some arrangements of the present disclosure. The package structure 4A is similar to the package structure 1 in FIG. 1, the package structure 2 in FIGS. 2A-2D, and/or the package structure 3 in FIGS. 3A-3C, and the differences therebetween are described as follows.

In some arrangements, the package structure 4A further includes connection elements 64 electrically connecting the electronic component 50 to the electronic component 70. In some arrangements, the surface 502 of the electronic component 50 is an active surface that electrically connects to the active surface (e.g., the surface 701) of the electronic component 70. The connection elements 6 include conductive bumps, e.g., solder bumps.

FIG. 4B is a cross-section of a package structure 4B in accordance with some arrangements of the present disclosure. FIG. 4C is a cross-section of a portion of a package structure 4B in accordance with some arrangements of the present disclosure. In some arrangements, FIG. 4C is a cross-section of a portion 4C of the package structure 4B illustrated in FIG. 4B. The package structure 4B is similar to the package structure 1 in FIG. 1, the package structure 2 in FIGS. 2A-2D, and/or the package structure 3 in FIGS. 3A-3C, and the differences therebetween are described as follows.

In some arrangements, the protective element 40 is or includes a pressure-sensitive protective element. In some arrangements, the protective element 40 covers the electronic component 20. In some arrangements, the protective element 40 contacts the electronic component 20. In some arrangements, the protective element 40 contacts the surface 101 of the substrate 10. In some arrangements, the lateral surface 403 of the protective element 40 is substantially aligned with the lateral surface 103 of the substrate 10. In some arrangements, the lateral surface 404 of the protective element 40 is substantially aligned with the lateral surface 104 of the substrate 10.

In some arrangements, the protective element 40 includes a silicone gel. In some arrangements, the protective element 40 is free of an epoxy material. In some arrangements, the protective element 40 includes fillers dispersed in the silicone gel.

Referring to FIG. 4C, in some arrangements, a roughness of the lateral surface (e.g., the lateral surfaces 403 and/or 404) of the protective element 40 is greater than a roughness of the lateral surface (e.g., the lateral surfaces 103 and/or 104) of the substrate 10. In some arrangements, the protective element 40 includes one or more protrusions 40r protruding from one or more lateral surfaces (e.g., the lateral surfaces 403 and/or 404) of the protective element 40. In some arrangements, the protrusion 40r partially covers one or more lateral surfaces (e.g., the lateral surfaces 103 and/or 104) of the substrate 10. In some arrangements, the protrusions 40r may be or include burrs. The protrusions 40r (or the burrs) may be formed by a mechanical cutting operation using a rotary saw blade during singulation. The relatively soft material of the protective element 40 may be pulled or dragged by the rotary saw blade and extending or stretched in the direction of the rotary saw blade's movement, such that the extended or stretched portions of the protective element 40 form the protrusions 40r (or the burrs) that partially cover one or more lateral surfaces (e.g., the lateral surfaces 103 and/or 104) of the substrate 10.

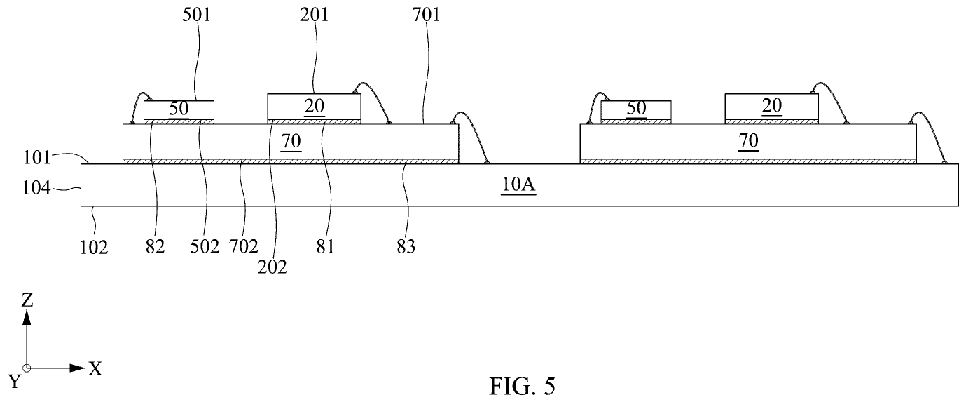

FIG. 5 to FIG. 8B illustrate various stages of an exemplary method of forming a package structure in accordance with some arrangements of the present disclosure.

Referring to FIG. 5, a substrate layer 10A may be provided, electronic components 70 may be connected to a surface 101 of the substrate layer 10A, and electronic components 20 and 50 may be connected to the electronic components 70.

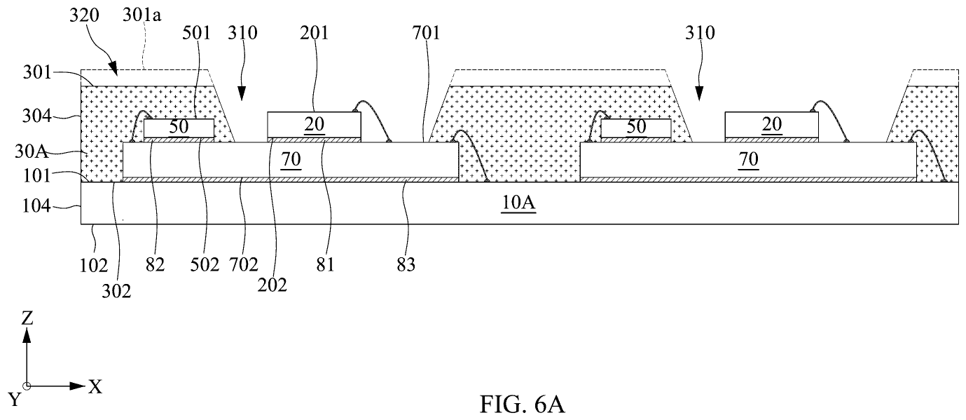

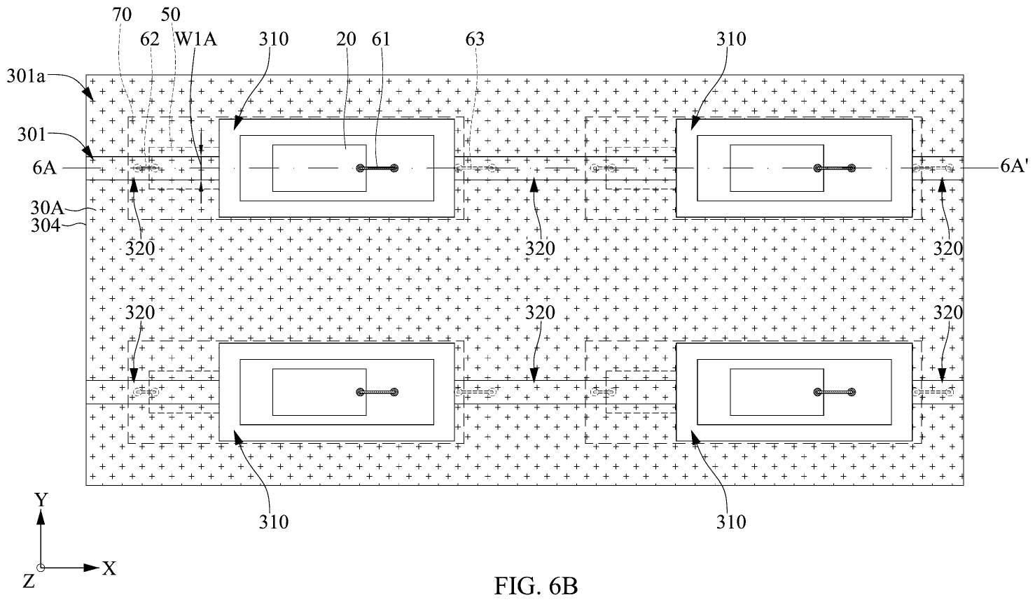

Referring to FIG. 6A and FIG. 6B, FIG. 6A is a cross-section along a line 6A-6A′ in FIG. 6B. An encapsulant layer 30A may be disposed or formed over the substrate layer 10A to encapsulate the electronic components 50 and portions of the electronic components 70. In some arrangements, the encapsulant layer 30A defines cavities 310 that expose the electronic components 20. In some arrangements, the encapsulant layer 30A further defines channels 320 (also referred to as “runner”) that extend toward and exposed by edges (e.g., the lateral surface 304) of the encapsulant layer 30A. The channels 320 may be defined by an upper surface 301 of the encapsulant layer 30A. In some arrangements, referring to FIG. 6A, the channels 320 are recessed from a top surface 301a, which is shown as a dashed line, of the encapsulant layer 30A.

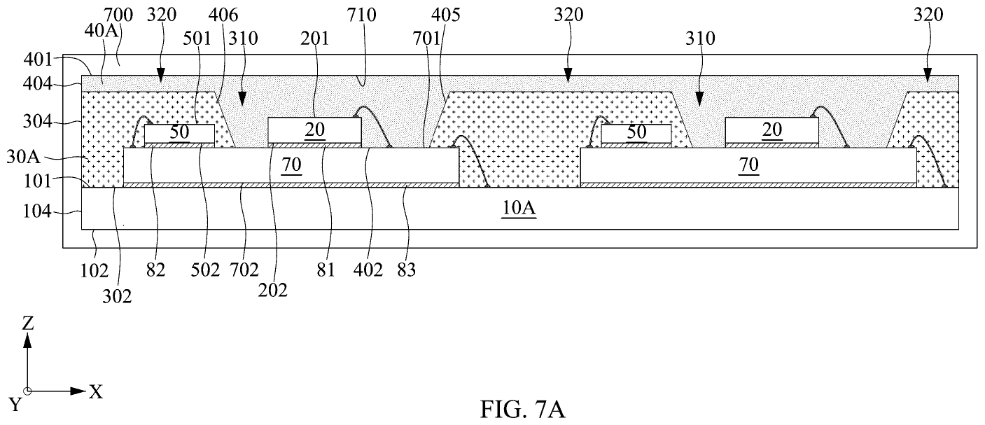

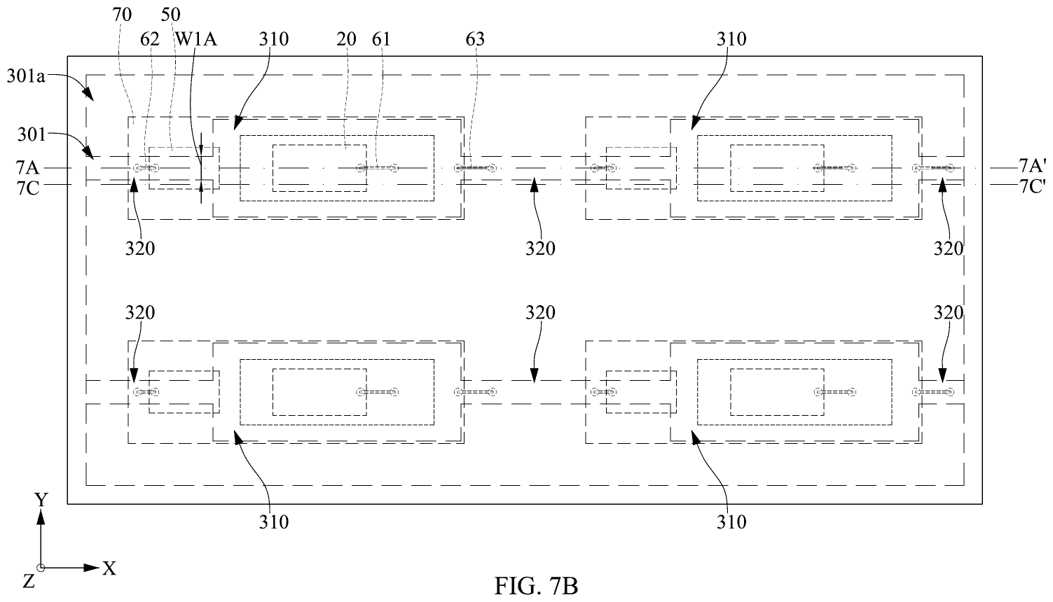

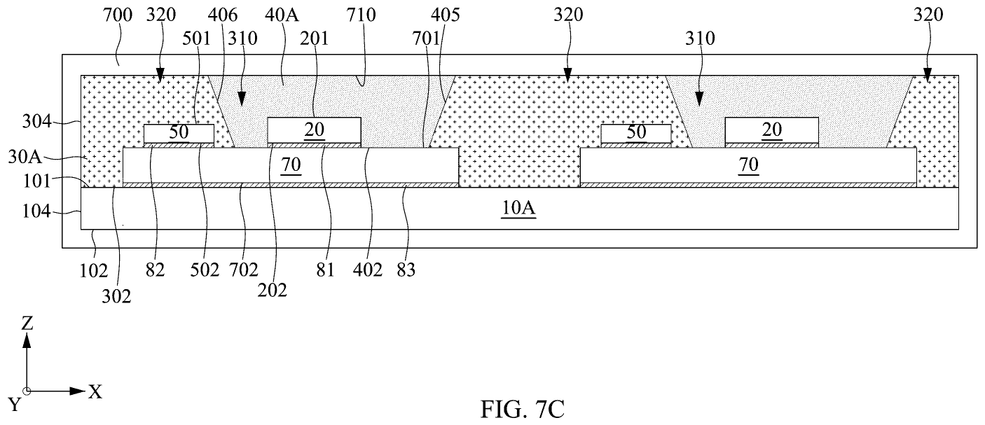

Referring to FIG. 7A, FIG. 7B, and FIG. 7C, FIG. 7A is a cross-section along a line 7A-7A′ in FIG. 7B, and FIG. 7C is a cross-section along a line 7C-7C′ in FIG. 7C. A protective material layer 40A may be formed in the cavities 310 and the channels 320. In some arrangements, the protective material layer 40A may be formed by a molding technique, e.g., transfer molding. In some arrangements, the structure illustrated in FIG. 6A and FIG. 6B is disposed in a mold 700 having an inner surface 710 facing the channels 320 and abutting the top surface 301a of the encapsulant layer 30A. Next, in some arrangements, a protective material may be provided into the mold 700 to flow over the channels 320 and fill into the cavities 310 and the channels 320, and then the protective material may be cured to form the protective material layer 40A. In some arrangements, the protective material is filled in the space enclosed or defined by the mold 700. In some arrangements, a top surface 401 of the protective material layer 40A is defined by the inner surface 710 of the mold 700.

According to some arrangements of the present disclosure, the top surface 401 of the protective material layer 40A (and the top surface 401 of the protective element 40 formed after singulation) is formed by pressing the protective material against the relatively planar inner surface 710 of the mold followed by curing the protective material, rather than by dispensing gel. Therefore, the top surface 401 of the protective material layer 40A can be as planar as the planar inner surface 710 of the mold 700, and the top surface 401 of the protective material layer 40A will not form a concave and recessed curved surface.

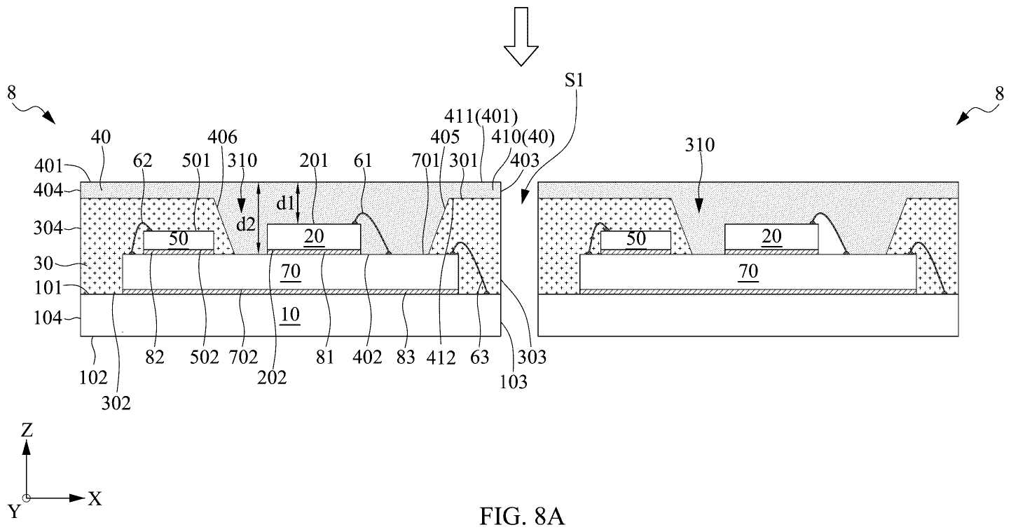

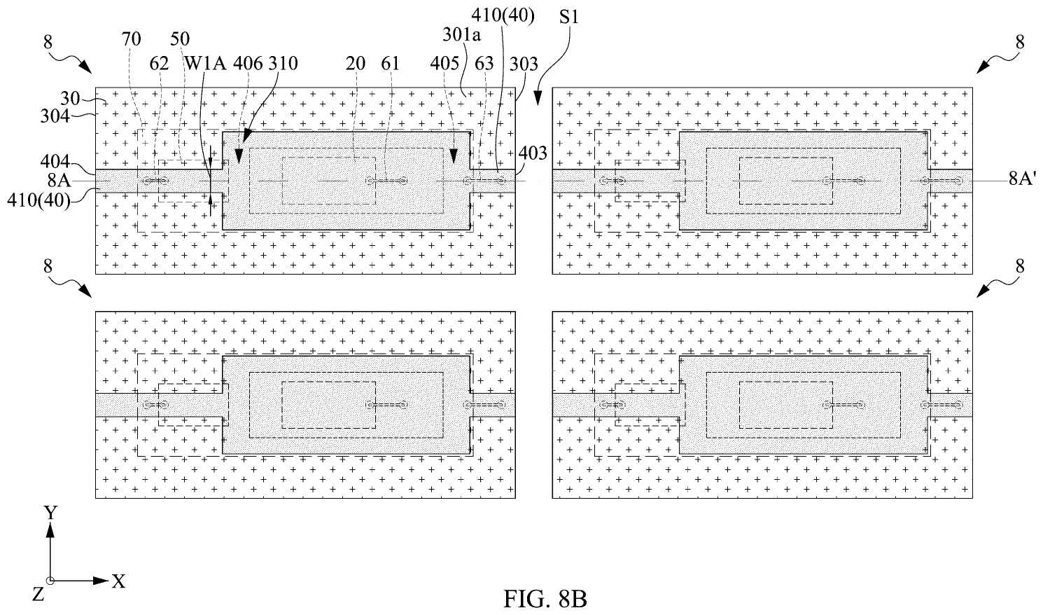

Referring to FIG. 8A and FIG. 8B, FIG. 8A is a cross-section along a line 8A-8A′ in FIG. 8B. The mold 700 may be removed, and a singulation operation may be performed on the as-formed structure to form a plurality of singulated structures 8. In some arrangements, the singulation operation may be performed by mechanical cutting or mechanical dicing. The singulation operation may be performed using a saw blade (e.g., a rotary saw blade). In some arrangements, the singulation operation may be performed by cutting or dicing along separation lines S1. In some arrangements, the singulated structure 8 may be the package structure 1, the package structure 2, the package structure 3, or the package structure 4A.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a first electronic component over the substrate;
an encapsulant over the substrate and defining a cavity exposing the first electronic component; and
a protective element covering the first electronic component, wherein a lateral surface of the protective element is substantially aligned with a lateral surface of the encapsulant.

2. The package structure as claimed in claim 1, wherein a roughness of the lateral surface of the protective element is greater than a roughness of the lateral surface of the encapsulant.

3. The package structure as claimed in claim 1, wherein the protective element comprises a pressure sensitive gel.

4. The package structure as claimed in claim 1, wherein the protective element is filled in the cavity and has a substantially planar top surface.

5. The package structure as claimed in claim 1, wherein a Shore hardness of the encapsulant is greater than a Shore hardness of the protective element.

6. The package structure as claimed in claim 1, wherein the encapsulant has a surface hardness from about 70 Shore D to 90 Shore D, and the protective element has a surface hardness from about 10 Shore OO to 30 Shore OO.

7. The package structure as claimed in claim 1, wherein an area of the lateral surface of the protective element is less than an area of the lateral surface of the encapsulant.

8. The package structure as claimed in claim 1, wherein a width of the lateral surface of the protective element is less than a width of the lateral surface of the encapsulant.

9. A package structure, comprising:
a substrate;
an encapsulant over the substrate and defining a cavity;
an electronic component disposed in the cavity; and
a protective element covering the electronic component and at least partially over an upper surface of the encapsulant.

10. The package structure as claimed in claim 9, wherein the protective element comprises a portion over the upper surface of the encapsulant and embedded in the encapsulant.

11. The package structure as claimed in claim 10, wherein the portion has a top surface and a lateral surface exposed by the encapsulant.

12. The package structure as claimed in claim 11, wherein the encapsulant has a top surface at an elevation higher than that of the upper surface with respect to a surface of the substrate, and the top surface of the portion is exposed by and substantially coplanar with the top surface of the encapsulant.

13. The package structure as claimed in claim 9, wherein the protective element is filled in the cavity and covers the upper surface of the encapsulant.

14. The package structure as claimed in claim 13, wherein the protective element comprises:
a first portion filled in the cavity; and
a second portion over the first portion and having a peripheral edge substantially aligned with a peripheral edge of the encapsulant.

15. The package structure as claimed in claim 9, wherein the protective element comprises a protrusion protruding from a lateral surface of the protective element.

16. The package structure as claimed in claim 15, wherein the protrusion partially covers a lateral surface of the encapsulant.

17. A package structure, comprising:
a substrate;
an electronic component over the substrate; and
a pressure-sensitive protective element covering the electronic component, wherein a lateral surface of the pressure-sensitive protective element is substantially aligned with a lateral surface of the substrate.

18. The package structure as claimed in claim 17, wherein the pressure-sensitive protective element comprises a silicone gel and an adhesive composition different from the silicone gel.

19. The package structure as claimed in claim 18, wherein the adhesive composition is free of an epoxy material.

20. The package structure as claimed in claim 18, wherein the pressure-sensitive protective element comprises fillers dispersed in the silicone gel.
